(19) United States
(12) Patent Application Publication
(10) Pub. No.: US 2023/0213599 A1
(43) Pub. Date: Jul. 6, 2023

(54) INVERSE ESTIMATION-BASED RADIUS CALCULATION METHOD AND SYSTEM FOR FERROMAGNETIC TARGET DETECTION

(71) Applicant: HUAZHONG UNIVERSITY OF SCIENCE AND TECHNOLOGY, Wuhan (CN)

(72) Inventors: Tianxu ZHANG, Wuhan (CN); Hanyu HONG, Wuhan (CN); Bin TIAN, Wuhan (CN); Yuehuan WANG, Wuhan (CN); Tao ZHANG, Wuhan (CN); Qinghui ZHANG, Wuhan (CN); Cheng YANG, Wuhan (CN); Jiawei WANG, Wuhan (CN); Jiandong TAN, Wuhan (CN)

(21) Appl. No.: 18/148,457

(22) Filed: Dec. 30, 2022

(30) Foreign Application Priority Data
Dec. 31, 2021 (CN) 2021116765183

(51) Int. Cl. G01R 33/022; G01V 3/08

(52) U.S. Cl. CPC G01R 33/022; G01V 3/081

(57) ABSTRACT

Disclosed is an inverse estimation-based radius calculation method and system for ferromagnetic target detection. The calculation method includes a data acquisition step and a ferromagnetic target detection radius calculation step. Distrubance of a scale model to power frequency electromagnetic waves is used to inversely estimate a corresponding ferromagnetic target detection radius. Inverse estimation is performed separately for an air layer and a sea water layer according to test results of multiple scale model tests and in consideration of both a stationary state and a motion state of the scale model, so as to acquire a ferromagnetic target detection radius calculation formula. Weights of factors such as mass, speed, depth, and height are great in inverse estimation, so that inverse estimation precision is improved. The majority of background noise interference can be screened out of the power frequency electromagnetic waves.

### TECHNICAL FIELD

The present invention pertains to the intersection of the technical field of non-acoustic underwater detection and the technical field of multi-dimensional signal processing, and more specifically relates to an inverse estimation-based radius calculation method and system for ferromagnetic target detection.

### BACKGROUND ART

In the context of the new landscape of economic globalization, mutual global trades occur extremely frequently. The total amount of the import and export of counties around the world, especially our country, increases rapidly. Shipping provides a huge volume of freight transport and efficient cargo protection, and is therefore favored by enterprises and merchants throughout the world. As a result, the number and tonnage of ships made by ship manufacturers increase year by year. Safety issues in the sailing process of ships have always been the focus of users.

Ferromagnetic objects such as shipwrecks and mines left by wars are subjects widely studied in marine exploration. Precise positioning needs to be performed for shipwreck salvaging and mine detection, and underwater shipwrecks and mines are also important elements affecting a marine navigation environment. In addition, ranges of activity of underwater vehicles and underwater robots increase constantly, and the underwater vehicles and the underwater robots have also become important elements affecting marine navigation. Detection of ferromagnetic targets such as shipwrecks and underwater vehicles is particularly important for traveling of ships.

A conventional underwater target detection means is typically a detection method based on sonar, that is, a sonar echo from a detected object is received to sense the direction and position of the target. Using sonar to detect an underwater target such as a shipwreck may have some problems. A shipwreck is often covered by marine sediment, and a sonar means is easily susceptible to disturbance caused by rugged topography of the seabed, thereby resulting in many false alarms for detection. In addition, acoustic detection requires a large number of detection arrays, is therefore costly, and is extremely vulnerable to background noise of the sea. It is very difficult for an acoustic detection means to perform large-distance wide-range detection for an underwater target concealed by background noise of the sea, so that the acoustic detection means cannot meet detection requirements of the vast sea of our country. Therefore, it is urgent to develop a novel non-acoustic remote-sensing detection means to detect an underwater target.

High-voltage power transmission, power transformation, and power consumption networks throughout the world generate power frequency electromagnetic waves. The power frequency electromagnetic waves have high penetrating performance, and can penetrate the sea to act on a ferromagnetic target. The ferromagnetic target may generate disturbance to the power frequency electromagnetic waves. A ferromagnetic target detection radius may then be calculated according to such disturbance.

A ferromagnetic target has a large range of activity, has great randomness of position, and is difficult to detect. A corresponding ferromagnetic target detection radius may be easily acquired by using a scale model to simulate a ferromagnetic target, using a sensor to acquire a disturbance signal generated when the ferromagnetic target generates disturbance to power frequency electromagnetic waves, acquiring a disturbance duration, and then performing inverse estimation.

Currently, a method for inversely estimating a corresponding ferromagnetic target detection radius according to disturbance of a scale model to power frequency electromagnetic waves is not available in the academic world.

To facilitate understanding of the present invention, related terms and concepts are explicated below:

Inverse estimation: an inversion problem refers to determining, from a result or some general principles or models, a parameter or a model parameter that represents a feature of a problem. Inverse estimation is a technical means used to solve an inversion problem. Inverse estimation refers to reaching a general conclusion according to a parameter of a model or test data, and applying the same to actual engineering applications.

Average field intensity: power frequency electromagnetic waves are generated by a high-voltage power transmission network, and an alternating current and an alternating magnetic field excite each other, so that an amplitude of magnetic field intensity of power frequency electromagnetic waves is not an absolutely fixed value, and fluctuates within a small range. However, when seen as a whole, the average magnetic field intensity of the power frequency electromagnetic waves can be regarded as a fixed value, that is, average field intensity.

Ferromagnetic target test: used to calculate a ferromagnetic target detection radius and including two types of tests: a ferromagnetic target stationary test and a ferromagnetic target motion test. The two types of tests have different test processes. The two types of test have the same test conditions: placing a ferromagnetic target below a sea surface, a ferromagnetic target detection platform being above the sea surface, and a sensor being fixed on the ferromagnetic target detection platform.

Ferromagnetic target stationary test: the test process comprises: keeping a ferromagnetic target stationary, and causing a ferromagnetic target detection platform to fly rectilinearly at a fixed flight speed along a predetermined flight course to pass a position directly above a scale model.

Ferromagnetic target motion test: the test process comprises either one of the following: 1) keeping a ferromagnetic target detection platform stationary, and causing a ferromagnetic target to move rectilinearly at a fixed movement speed along a predetermined course to pass a position directly under the ferromagnetic target detection platform; and 2) causing a ferromagnetic target detection platform to fly rectilinearly at a fixed flight speed along a predetermined flight course, and causing a ferromagnetic target to move rectilinearly at a fixed movement speed along a predetermined course to pass a position directly under the ferromagnetic target detection platform.

Scale model: a scale model of a ferromagnetic target, the mass and speed of the scale model being proportional to the mass and speed of the ferromagnetic target.

Scale model test: used to simulate a ferromagnetic target test and including two types of tests: a scale model stationary test and a scale model motion test. The two types of tests have different test processes. The two types of tests have the same test conditions: placing a scale model below a sea surface, an unmanned aerial vehicle above the sea surface serving as a detection platform of the scale model, and a sensor being fixed on the unmanned aerial vehicle. The two types of tests have the same test result: a disturbance duration is acquired by means of the sensor on the unmanned aerial vehicle.

Scale model stationary test: used to simulate a ferromagnetic target stationary test. The test process comprises: keeping a scale model stationary, and causing an unmanned aerial vehicle to fly rectilinearly at a fixed flight speed along a predetermined flight course to pass a position directly above the scale model. Specifications of a sensor used in the test are consistent with specifications of a sensor in a corresponding ferromagnetic target stationary test.

Scale model motion test: used to simulate a ferromagnetic target motion test. The test process comprises either one of the following: 1) keeping an unmanned aerial vehicle stationary, and causing a scale model to move rectilinearly at a fixed movement speed along a predetermined course to pass a position directly under the unmanned aerial vehicle; and 2) causing an unmanned aerial vehicle to fly rectilinearly at a fixed flight speed along a predetermined flight course, and causing a scale model to move rectilinearly at a fixed movement speed along a predetermined course to pass a position directly under the unmanned aerial vehicle. Specifications of a sensor used in the test are consistent with specifications of a sensor in a corresponding ferromagnetic target motion test.

Disturbance duration: in a scale model stationary test and a scale model motion test, no matter a scale model is in motion or is stationary, the scale model generates disturbance to power frequency electromagnetic waves, and when the disturbance is generated, the intensity of the power frequency electromagnetic waves is greater than average field intensity within a duration. This duration is equivalent to the disturbance duration.

Model detection radius: in a scale model stationary test and a scale model motion test, no matter a scale model is in motion or is stationary, the scale model generates disturbance to power frequency electromagnetic waves. A range in which the disturbance is present forms a circle with the scale model being the center of the circle, and the radius of the circle is the model detection radius.

Ferromagnetic target detection radius: no matter a ferromagnetic target is in motion or is stationary, the ferromagnetic target generates disturbance to power frequency electromagnetic waves. A range in which the disturbance is present forms a circle with the ferromagnetic target being the center of the circle, and the radius of the circle is the ferromagnetic target detection radius.

Detection included angle: an included angle formed by a connecting line between a front end point of a detection target and a detection point and a sea surface. The front end point of the detection target is the foremost end point of the detection target in a movement direction. The detection target may be a ferromagnetic target or a scale model. The detection point may be a ferromagnetic target detection platform or an unmanned aerial vehicle. At least one of the detection target and the detection point is in motion, so that the value of the detection included angle changes in real time.

Ferromagnetic target included angle: when a detection target is a ferromagnetic target, and a detection point is a ferromagnetic target detection platform, and when the ferromagnetic target is directly under the ferromagnetic target detection platform, a formed detection included angle is the ferromagnetic target included angle.

Scale model included angle: when a detection target is a scale model, and a detection point is an unmanned aerial vehicle, and when the scale model is directly under the unmanned aerial vehicle, a formed detection included angle is the scale model included angle.

### SUMMARY OF THE INVENTION

In view of the defects of the prior art, an objective of the present invention is to provide an inverse estimation-based radius calculation method and system for ferromagnetic target detection, aiming to achieve the goal of inversely estimating a corresponding ferromagnetic target detection radius according to disturbance of a scale model to power frequency electromagnetic waves.

In order to achieve the above-described objective, the present invention provides an inverse estimation-based radius calculation method for ferromagnetic target detection, the method being used to inversely estimate, according to a test result of a single scale model stationary test or scale model motion test, a ferromagnetic target detection radius R in a corresponding ferromagnetic target stationary test or ferromagnetic target motion test, and the method comprising the following steps:
(1) a data acquisition step:
   respectively acquiring values of a model detection radius r, a ratio p of the mass of a ferromagnetic target to the mass of a scale model, a diving depth L₁ of the ferromagnetic target, a depth L₂ of the scale model in sea water, an attenuation index n₁ of power frequency electromagnetic wave intensity in an air layer with respect to a distance, a height l₁ of a ferromagnetic target detection platform, a flight height l₂ of an unmanned aerial vehicle, a speed V of the ferromagnetic target, a speed v of the scale model, an orientation change speed V_{∂} of the ferromagnetic target, an orientation change speed v_{∂} of the scale model, a ferromagnetic target included angle θ₁, and a scale model included angle θ₂, a diameter D of the ferromagnetic target, and a diameter d of the scale model,
   wherein the value of r is calculated by using the following formula: r = t × v1 ÷ 2, t being a disturbance duration, v1 being a flight speed of the unmanned aerial vehicle, and the value of t being the test result of the single scale model test; and
(2) a ferromagnetic target detection radius calculation step:
   calculating the ferromagnetic target detection radius R according to the following formula:
$$\frac{R}{r} = \frac{- \frac{π \text{} S I}{{λ}^{2} {r}_{0}} {e}^{- {k}_{1} {L}_{1}} \left(1 + V + {\text{V}}_{\partial } ⋅ \text{D}\right) M ⋅ s i n {θ}_{1} \frac{1}{{k}_{2} {l}_{1} {}^{{n}_{1}}}}{- \frac{π \text{} S I}{{λ}^{2} {r}_{0}} {e}^{- {k}_{1} {L}_{2}} \left(1 + v + {v}_{\partial } ⋅ \text{d}\right) m ⋅ s i n {θ}_{2} \frac{1}{{k}_{2} {l}_{2} {}^{{n}_{1}}}}$$
where e is a base number of a natural logarithm, k₁ is an attenuation coefficient of sea water to a magnetic field, and k₂ is an attenuation coefficient of air to the magnetic field.

Preferably, a derivation process of the formula in the ferromagnetic target detection radius calculation step comprises:
(1) acquiring the following empirical formulas according to test results of multiple scale model tests:
$$\frac{{H}_{{θ}_{2}}}{{H}_{{θ}_{1}}} = \frac{1}{{k}_{2} {a}^{{n}_{1}}} ;$$
$$\frac{{H}_{{θ}_{2}}}{{H}_{{θ}_{1}}} = {\text{e}}^{- {k}_{1} {b}^{{n}_{2}}}$$
wherein H_{θ2} and H_{θ1} are respectively power frequency electromagnetic wave intensities at two different points in the same medium layer, a is a distance between two points in the air layer, b is a distance between two points in the sea water layer, the medium layer is the air layer or the sea water layer, and the multiple scale model tests comprise a scale model stationary test and a scale model motion test;
(2) performing inverse estimation separately for the air layer and the sea water layer according to the test results and the empirical formulas and in consideration of both a stationary state and a motion state of the scale model, while assigning the value of h to a and assigning the value of H to b, so as to acquire an empirical formula for calculating a power frequency electromagnetic wave intensity H_{θ}:
$${H}_{θ} = - \frac{π \text{} S I}{{λ}^{2}} \left({\text{e}}^{- {k}_{1} {H}^{{n}_{2}}} + \frac{1}{{k}_{2} {h}^{{n}_{1}}}\right) m \left(1 + {v}_{0}\right) s i n θ$$
where π is Pi, S is a total area of a dipole group, I is current intensity, λ, is a wavelength of power frequency electromagnetic waves, m is the mass of the scale model, ν₀ is a movement speed of a detection target, θ is a detection included angle, H is a depth of the detection target in sea water, and h is a height of a detection point; and
(3) performing inverse estimation according to the empirical formula for H_{θ} to acquire a ferromagnetic target detection radius calculation formula:
$$\frac{R}{r} = \frac{- \frac{π \text{} S I}{{λ}^{2}} \left({\text{e}}^{- {k}_{1} {H}_{1} {}^{{n}_{2}}} + \frac{1}{{k}_{2} {h}_{1} {}^{{n}_{1}}}\right) M \left(1 + V\right) s i n {θ}_{1}}{- \frac{π \text{} S I}{{λ}^{2}} \left({\text{e}}^{- {k}_{1} {H}_{2} {}^{{n}_{2}}} + \frac{1}{{k}_{2} {h}_{2} {}^{{n}_{1}}}\right) m \left(1 + v\right) s i n {θ}_{2}}$$
wherein said formula is used to acquire the formula in the ferromagnetic target detection radius calculation step.

Preferably, H₂ and h₂ both have multiple different values in each of the multiple scale model tests.

Preferably, in the data acquisition step, n₁ and n2 are both preset natural numbers, the value of k₁ is 0.357, and the value of k₂ is 61.24.

The present invention provides an inverse estimation-based radius calculation system for ferromagnetic target detection, the system being used to inversely estimate, according to a test result of a single scale model stationary test or scale model motion test, a ferromagnetic target detection radius R in a corresponding ferromagnetic target stationary test or ferromagnetic target motion test, and the system comprising the following modules:
a data acquisition module, configured to perform the following:
respectively acquiring values of a model detection radius r, a ratio p of the mass of a ferromagnetic target to the mass of a scale model, a diving depth H₁ of the ferromagnetic target, a depth H₂ of the scale model in sea water, an attenuation index n₁ of power frequency electromagnetic wave intensity in an air layer with respect to a distance, an attenuation index n2 of power frequency electromagnetic wave intensity in a sea water layer with respect to a distance, a height h₁ of a ferromagnetic target detection platform, a flight height h₂ of an unmanned aerial vehicle, a speed V of the ferromagnetic target, a speed v of the scale model, a ferromagnetic target included angle θ₁, and a scale model included angle θ₂,
wherein the value of r is calculated by using the following formula: r = t × v1 ÷ 2, t being a disturbance duration, v1 being a flight speed of the unmanned aerial vehicle, and the value of t being the test result of the single scale model test; and
a ferromagnetic target detection radius calculation module, configured to perform the following:
calculating the ferromagnetic target detection radius R according to the following formula:
$$\frac{R}{r} = p \frac{\left({\text{e}}^{- {k}_{1} {H}_{1} {}^{{n}_{2}}} + \frac{1}{{k}_{2} {h}_{1} {}^{{n}_{1}}}\right) \left(1 + V\right) s i n {θ}_{1}}{\left({\text{e}}^{- {k}_{1} {H}_{2} {}^{{n}_{2}}} + \frac{1}{{k}_{2} {h}_{2} {}^{{n}_{1}}}\right) \left(1 + v\right) s i n {θ}_{2}}$$
where e is a base number of a natural logarithm, k₁ is an attenuation coefficient of sea water to a magnetic field, and k₂ is an attenuation coefficient of air to the magnetic field.

Preferably, a derivation operation of the formula in the ferromagnetic target detection radius calculation module comprises:
(1) acquiring the following empirical formulas according to test results of multiple scale model tests:
$$\frac{{H}_{{θ}_{2}}}{{H}_{{θ}_{1}}} = \frac{1}{{k}_{2} {l}_{1} {}^{{n}_{1}}} ;$$
$$\frac{{H}_{{θ}_{2}}}{{H}_{{θ}_{1}}} = {\text{e}}^{- {k}_{1} {L}_{1}}$$
wherein H_{θ2} and H_{θ1} are respectively power frequency electromagnetic wave intensities at two different points in the same medium layer, l₁ is a distance between two points in the air layer, L₁ is a distance between two points in the sea water layer, the medium layer is the air layer or the sea water layer, and the multiple scale model tests comprise a scale model stationary test and a scale model motion test;
(2) performing inverse estimation separately for the air layer and the sea water layer according to the test results and the empirical formulas and in consideration of both a stationary state and a motion state of the scale model, so as to acquire an empirical formula for calculating a power frequency electromagnetic wave intensity B₂:
$${B}_{2} = - \frac{π \text{} S I}{{λ}^{2} {r}_{0}} {\text{e}}^{- {k}_{1} {L}_{2}} \left(1 + v + {v}_{\partial } ⋅ d\right) m ⋅ s i n {θ}_{2} \frac{1}{{k}_{2} {l}_{2} {}^{{n}_{1}}}$$
where π is Pi, S is a total area of a dipole group, I is current intensity, λ, is a wavelength of power frequency electromagnetic waves, m is the mass of the scale model, ν₀ is a movement speed of the scale model, ν_{∂} is an orientation change speed of the scale model, d is a diameter of the scale model, θ is a detection included angle, L₂ is a depth of the scale model in sea water, and l₂ is a height of a detection point; and
(3) performing inverse estimation according to the empirical formula for B₂ to acquire a ferromagnetic target detection radius calculation formula:
$$\frac{R}{r} = \frac{- \frac{π \text{} S I}{{λ}^{2} {r}_{0}} {e}^{- {k}_{1} {L}_{1}} \left(1 + V + {\text{V}}_{\partial } ⋅ \text{D}\right) M ⋅ s i n {θ}_{1} \frac{1}{{k}_{2} {l}_{1} {}^{{n}_{1}}}}{- \frac{π \text{} S I}{{λ}^{2} {r}_{0}} {e}^{- {k}_{1} {L}_{2}} \left(1 + v + {v}_{\partial } ⋅ \text{d}\right) m ⋅ s i n {θ}_{2} \frac{1}{{k}_{2} {l}_{2} {}^{{n}_{1}}}}$$
wherein said formula is used to acquire the formula in the ferromagnetic target detection radius calculation module.

Preferably, L₂ and l₂ both have multiple different values in each of the multiple scale model tests.

Preferably, in the data acquisition module, n₁ is a preset natural number, the value of k₁ is 0.357, and the value of k₂ is 61.24.

The present invention provides an inverse estimation-based radius calculation device for ferromagnetic target detection, comprising a memory and a processor, wherein the memory is used to store a computer program, and the processor, when executing the computer program, implements the inverse estimation-based radius calculation method for ferromagnetic target detection described above.

The present invention provides a computer-readable storage medium, wherein the storage medium stores a computer program, and when executed by a processor, the computer program implements the inverse estimation-based radius calculation method for ferromagnetic target detection described above.

By means of the above technical solution contemplated in the present invention, compared with the prior art, the present invention provides a method for inversely estimating a corresponding ferromagnetic target detection radius according to disturbance of a scale model to power frequency electromagnetic waves. In the present invention, inverse estimation is performed separately for an air layer and a sea water layer according to test results of multiple scale model tests and in consideration of both a stationary state and a motion state of the scale model, so as to acquire a ferromagnetic target detection radius calculation formula. Since the sea is mostly a far-field region of power frequency electromagnetic waves, weights of factors such as mass, speed, depth, and height are great in inverse estimation, so that inverse estimation precision is improved.

Power frequency electromagnetic waves can be used to measure a disturbance signal without requiring a large number of excitation sources. In addition, power frequency electromagnetic waves are very low-frequency electromagnetic waves, so that the majority of background noise interference can be screened out. The power frequency electromagnetic waves have a large wavelength and a long propagation distance, and so can also be used to perform signal detection in a far-field region, thereby meeting the requirements of large-range detection in the sea. Therefore, the present invention can be used to perform large-distance wide-range detection for a ferromagnetic target concealed by background noise of the sea.

### BRIEF DESCRIPTION OF THE DRAWINGS

FIG. 1 is a flowchart of an inverse estimation-based radius calculation method for ferromagnetic target detection according to an embodiment of the present invention; and

FIG. 2 is schematic diagram of a detection included angle formed when a detection target is directly under a detection point in an inverse estimation-based radius calculation method for ferromagnetic target detection according to an embodiment of the present invention.

### DETAILED DESCRIPTION

In order to make the objective, technical solution, and advantages of the present invention clearer, the following detailed description of the present invention is provided with reference to the accompanying drawings and embodiments. It is to be understood that specific embodiments described herein are used merely to explain the present invention, and are not used to limit the present invention.

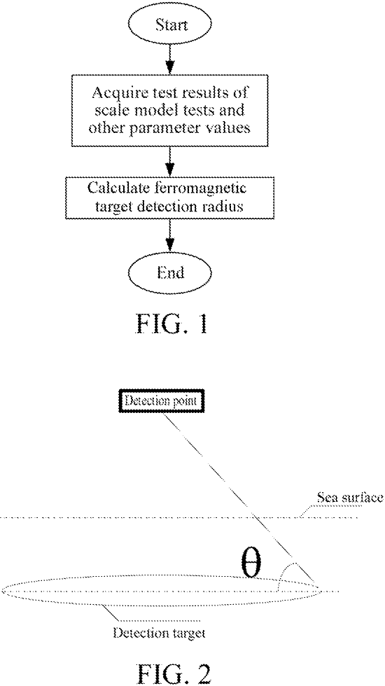

As shown in FIG. 1, the present embodiment provides an inverse estimation-based radius calculation method for ferromagnetic target detection, the method being used to inversely estimate, according to a test result of a single scale model stationary test or scale model motion test, a ferromagnetic target detection radius R in a corresponding ferromagnetic target stationary test or ferromagnetic target motion test. The method includes the following steps:
(1) a data acquisition step:
   respectively acquiring values of a model detection radius r, a ratio p of the mass of a ferromagnetic target to the mass of a scale model, a diving depth L₁ of the ferromagnetic target, a depth L₂ of the scale model in sea water, an attenuation index n₁ of power frequency electromagnetic wave intensity in an air layer with respect to a distance, a height l₁ of a ferromagnetic target detection platform, a flight height l₂ of an unmanned aerial vehicle, a speed V of the ferromagnetic target, a speed v of the scale model, an orientation change speed V_{∂} of the ferromagnetic target, an orientation change speed ν_{∂} of the scale model, a diameter D of the ferromagnetic target, a diameter d of the scale model, a ferromagnetic target included angle θ₁, and a scale model included angle θ₂,
   wherein L₁ = 120 m, L₂ = 19 m, l₁ = 5000 m, l₂ = 10 m, v = 0.5 m/s, V = 20 m/s, sinθ₁ = 1, and sinθ₂ = 0.98, the mass of the scale model is 2.3 tons, and the ferromagnetic target is an underwater vehicle, and has a mass of 9000 tons.

The value of r is 112 m, and is calculated by using the following formula: r = t × v1 ÷ 2. t is a disturbance duration, and has a value of 44.8 s. v1 is a flight speed of the unmanned aerial vehicle, and has a value of 5 m/s.

The value of t is the test result of the single scale model test. In the test, a sampling rate of a sensor is 1024 Hz, and an analysis frequency is 50 Hz. Compared with conventional acoustic detection, attenuation of power frequency electromagnetic waves caused by sea water is weak, so that the power frequency electromagnetic waves have a high capability of penetrating the sea water layer. The power frequency electromagnetic waves do not cause large changes in electromagnetic signals due to changes in submarine topography, such that a disturbance signal does not include too much clutter. The power frequency electromagnetic waves are spatially evenly distributed, and the disturbance signal is clear, so that the disturbance signal can be acquired without extremely complex processing, thereby acquiring the disturbance duration.

a ferromagnetic target detection radius calculation step:
calculating the ferromagnetic target detection radius R according to the following formula, a value thereof being 21.74 km:
$$\frac{R}{r} = \frac{- \frac{π \text{} S I}{{λ}^{2} {r}_{0}} {e}^{- {k}_{1} {L}_{1}} \left(1 + V + {\text{V}}_{\partial } ⋅ \text{D}\right) M ⋅ s i n {θ}_{1} \frac{1}{{k}_{2} {l}_{1} {}^{{n}_{1}}}}{- \frac{π \text{} S I}{{λ}^{2} {r}_{0}} {e}^{- {k}_{1} {L}_{2}} \left(1 + v + {v}_{\partial } ⋅ \text{d}\right) m ⋅ s i n {θ}_{2} \frac{1}{{k}_{2} {l}_{2} {}^{{n}_{1}}}}$$
where e is a base number of a natural logarithm, k₁ is an attenuation coefficient of sea water to a magnetic field, and has a value of 0.357, k₂ is an attenuation coefficient of air to the magnetic field, and has a value of 61.24, and n₁ is a preset natural number. The value of n₁ may be the same, or may be different. In this embodiment, the value of n₁ is 1.

A derivation process of the formula comprises:
(1) The following empirical formulas are acquired according to test results of multiple scale model tests:
$$\frac{{H}_{{θ}_{2}}}{{H}_{{θ}_{1}}} = \frac{1}{{k}_{2} {l}_{1} {}^{{n}_{1}}} ;$$
$$\frac{{H}_{{θ}_{2}}}{{H}_{{θ}_{1}}} = {\text{e}}^{- {k}_{1} {L}_{1}}$$
wherein H_{θ2} and H_{θ1} are respectively power frequency electromagnetic wave intensities at two different points in the same medium layer, l₁ is a distance between two points in the air layer, L₁ is a distance between two points in the sea water layer, the medium layer is the air layer or the sea water layer, and the multiple scale model tests include a scale model stationary test and a scale model motion test. L₂ and l₂ both have multiple different values in each of the multiple scale model tests. In this embodiment, L₂ has six values in total and L₂ ≤ 30 m, and l₂ has seven values in total and l₂ ≤ 50 m.

The power frequency electromagnetic waves are generated by a high-voltage power transmission network, and an alternating current and an alternating magnetic field excite each other. A power frequency high-voltage power grid is equivalent to a dipole group, and serves as a signal source of the power frequency electromagnetic waves. A signal of the power frequency electromagnetic waves is in a positive proportional relationship to both a total area of the dipole group and the current intensity in the power transmission network. The power frequency electromagnetic waves have a fixed time-varying period, and the scale model can still generate disturbance to the power frequency electromagnetic waves when the scale model is stationary, so that a case in which the speed of the scale model is zero needs to be considered. In addition, different media attenuate the power frequency electromagnetic waves differently, so that inverse estimation needs to be performed separately for the air layer and the sea water layer.

Inverse estimation is performed separately for the air layer and the sea water layer according to the test results and the empirical formulas and in consideration of both a stationary state and a motion state of the scale model, so as to acquire an empirical formula for calculating a power frequency electromagnetic wave intensity B₂:

$${B}_{2} = - \frac{π \text{} S I}{{λ}^{2} {r}_{0}} {e}^{- {k}_{1} {L}_{2}} \left(1 + v + {v}_{\partial } ⋅ d\right) m ⋅ s i n {θ}_{2} \frac{1}{{k}_{2} {l}_{2} {}^{{n}_{1}}}$$

where π is Pi, S is a total area of a dipole group, I is current intensity, λ, is a wavelength of power frequency electromagnetic waves, m is the mass of the scale model, ν₀ is a movement speed of a detection target, H is a depth of the detection target in sea water, l₂ is a height of a detection point, ν_{∂} is an orientation change speed of the scale model, d is a diameter of the target, and θ is a detection included angle, as shown in FIG. 2.

Inverse estimation is performed according to the empirical formula for B₂ to acquire a ferromagnetic target detection radius calculation formula:

$$\frac{R}{r} = \frac{- \frac{π \text{} S I}{{λ}^{2} {r}_{0}} {e}^{- {k}_{1} {L}_{1}} \left(1 + V + {\text{V}}_{\partial } ⋅ \text{D}\right) M ⋅ s i n {θ}_{1} \frac{1}{{k}_{2} {l}_{1} {}^{{n}_{1}}}}{- \frac{π \text{} S I}{{λ}^{2} {r}_{0}} {e}^{- {k}_{1} {L}_{2}} \left(1 + v + {v}_{\partial } ⋅ \text{d}\right) m ⋅ s i n {θ}_{2} \frac{1}{{k}_{2} {l}_{2} {}^{{n}_{1}}}}$$

Said formula is used to acquire the formula in the ferromagnetic target detection radius calculation step. Since the sea is mostly a far-field region of power frequency electromagnetic waves, weights of factors such as mass, speed, depth, and height are great in inverse estimation, so that inverse estimation precision is improved.

In the ferromagnetic target detection radius calculation step, a calculation process of the values of k₁ and k₂ is as follows:

Since air and sea water have different physical parameters and have different absorptive actions with respect to electromagnetic waves, the attenuation coefficient k is calculated according to the following formula:

$$\text{k} \text{=} ω \sqrt{\frac{μ \text{} ε}{2} \left(1 + \frac{{σ}^{2}}{{ω}^{2} {ε}^{2}}\right) + 1}$$

where ω is an angular frequency of electromagnetic waves, σ is the conductivity of a medium, µ is the magnetic permeability of the medium, and ε is a dielectric constant of the medium. Calculation is performed according to physical properties of sea water and air and parameters thereof, so as to obtain: k₁ = 0.357, and k₂ = 61.24.

Power frequency electromagnetic waves can be used to measure a disturbance signal without requiring a large number of excitation sources. In addition, power frequency electromagnetic waves are very low-frequency electromagnetic waves, so that the majority of background noise interference can be screened out. The power frequency electromagnetic waves have a large wavelength and a long propagation distance, and so can also be used to perform signal detection in a far-field region, thereby meeting the requirements of large-range detection in the sea. Therefore, the inverse estimation-based radius calculation method for ferromagnetic target detection in this embodiment can be used to perform large-distance wide-range detection for a ferromagnetic target concealed by background noise of the sea.

The present embodiment provides an inverse estimation-based radius calculation system for ferromagnetic target detection, the system being used to inversely estimate, according to a test result of a single scale model stationary test or scale model motion test, a ferromagnetic target detection radius R in a corresponding ferromagnetic target stationary test or ferromagnetic target motion test. The system includes the following modules:
a data acquisition module, configured to perform the following:
respectively acquiring values of a model detection radius r, a ratio p of the mass of a ferromagnetic target to the mass of a scale model, a diving depth L₁ of the ferromagnetic target, a depth L₂ of the scale model in sea water, an attenuation index n₁ of power frequency electromagnetic wave intensity in an air layer with respect to a distance, a height l₁ of a ferromagnetic target detection platform, a flight height l₂ of an unmanned aerial vehicle, a speed V of the ferromagnetic target, a speed v of the scale model, an orientation change speed V_{∂} of the ferromagnetic target, an orientation change speed ν_{∂} of the scale model, a diameter D of the ferromagnetic target, a diameter d of the scale model, a ferromagnetic target included angle θ₁, and a scale model included angle θ₂,
wherein r is calculated by using the following formula: r = t × v1 ÷ 2, t being a disturbance duration, v1 being a flight speed of the unmanned aerial vehicle, and the value of t being the test result of the single scale model test; and
a ferromagnetic target detection radius calculation module, configured to perform the following:
calculating the ferromagnetic target detection radius R according to the following formula:
$$\frac{R}{r} = \frac{- \frac{π \text{} S I}{{λ}^{2} {r}_{0}} {e}^{- {k}_{1} {L}_{1}} \left(1 + V + {\text{V}}_{\partial } ⋅ \text{D}\right) M ⋅ s i n {θ}_{1} \frac{1}{{k}_{2} {l}_{1} {}^{{n}_{1}}}}{- \frac{π \text{} S I}{{λ}^{2} {r}_{0}} {e}^{- {k}_{1} {L}_{2}} \left(1 + v + {v}_{\partial } ⋅ \text{d}\right) m ⋅ s i n {θ}_{2} \frac{1}{{k}_{2} {l}_{2} {}^{{n}_{1}}}}$$
where e is a base number of a natural logarithm, k₁ is an attenuation coefficient of sea water to a magnetic field, k₂ is an attenuation coefficient of air to the magnetic field, and n₁ is a preset natural number.

A derivation operation of the formula comprises:
(1) acquiring the following empirical formulas according to test results of multiple scale model tests:
$$\frac{{H}_{{θ}_{2}}}{{H}_{{θ}_{1}}} = \frac{1}{{k}_{2} {l}_{1} {}^{{n}_{1}}} ;$$
$$\frac{{H}_{{θ}_{2}}}{{H}_{{θ}_{1}}} = {\text{e}}^{- {k}_{1} {L}_{1}}$$
wherein H_{θ2} and H_{θ1} are respectively power frequency electromagnetic wave intensities at two different points in the same medium layer, l₁ is a distance between two points in the air layer, L₁ is a distance between two points in the sea water layer, the medium layer is the air layer or the sea water layer, the multiple scale model tests include a scale model stationary test and a scale model motion test, and L₂ and l₂ both have multiple different values in each of the multiple scale model tests.

performing inverse estimation separately for the air layer and the sea water layer according to the test results and the empirical formulas and in consideration of both a stationary state and a motion state of the scale model, so as to acquire an empirical formula for calculating a power frequency electromagnetic wave intensity B₂:

$${B}_{2} = - \frac{π \text{} S I}{{λ}^{2} {r}_{0}} {\text{e}}^{- {k}_{1} {L}_{2}} \left(1 + v + {v}_{\partial } ⋅ d\right) m ⋅ s i n {θ}_{2} \frac{1}{{k}_{2} {l}_{2} {}^{{n}_{1}}}$$

where π is Pi, S is a total area of a dipole group, I is current intensity, λ, is a wavelength of power frequency electromagnetic waves, m is the mass of the scale model, ν is a movement speed of the scale model, L₂ is a depth of the detection target in sea water, l₂ is a height of a detection point, ν_{∂} is an orientation change speed of the scale model, d is a diameter of the scale model, and θ is a detection included angle.

performing inverse estimation according to the empirical formula for B₂ to acquire a ferromagnetic target detection radius calculation formula:

$$\frac{R}{r} = \frac{- \frac{π \text{} S I}{{λ}^{2} {r}_{0}} {e}^{- {k}_{1} {L}_{1}} \left(1 + V + {\text{V}}_{\partial } ⋅ \text{D}\right) M ⋅ s i n {θ}_{1} \frac{1}{{k}_{2} {l}_{1} {}^{{n}_{1}}}}{- \frac{π \text{} S I}{{λ}^{2} {r}_{0}} {e}^{- {k}_{1} {L}_{2}} \left(1 + v + {v}_{\partial } ⋅ \text{d}\right) m ⋅ s i n {θ}_{2} \frac{1}{{k}_{2} {l}_{2} {}^{{n}_{1}}}}$$

wherein said formula is used to acquire the formula in the ferromagnetic target detection radius calculation module.

In the ferromagnetic target detection radius calculation module, a calculation operation of the values of k₁ and k₂ is as follows:

Since air and sea water have different physical parameters and have different absorptive actions with respect to electromagnetic waves, the attenuation coefficient k is calculated according to the following formula:

$$\text{k} \text{=} ω \sqrt{\frac{μ \text{} ε}{2} \left(1 + \frac{{σ}^{2}}{{ω}^{2} {ε}^{2}}\right) + 1}$$

where ω is an angular frequency of electromagnetic waves, σ is the conductivity of a medium, µ is the magnetic permeability of the medium, and ε is a dielectric constant of the medium. Calculation is performed according to physical properties of sea water and air and parameters thereof, so as to obtain: k₁ = 0.357, and k₂ = 61.24.

It can be easily understood by those skilled in the art that the foregoing description is only preferred embodiments of the present invention and is not intended to limit the present invention. All the modifications, identical replacements and improvements within the spirit and principle of the present invention should be in the scope of protection of the present invention.

1. An inverse estimation-based radius calculation method for ferromagnetic target detection, the method being used to inversely estimate, according to a test result of a single scale model stationary test or scale model motion test, a ferromagnetic target detection radius R in a corresponding ferromagnetic target stationary test or ferromagnetic target motion test, and the method comprising the following steps:
(1) a data acquisition step:
respectively acquiring values of a model detection radius r, a ratio p of the mass of a ferromagnetic target to the mass of a scale model, a diving depth L₁ of the ferromagnetic target, a depth L₂ of the scale model in sea water, an attenuation index n₁ of power frequency electromagnetic wave intensity in an air layer with respect to a distance, a height l₁ of a ferromagnetic target detection platform, a flight height l₂ of an unmanned aerial vehicle, a speed V of the ferromagnetic target, a speed v of the scale model, a ferromagnetic target included angle θ₁, a scale model included angle θ₂, an orientation change speed V_{∂} of the ferromagnetic target, and an orientation change speed v_{∂} of the scale model,
wherein the value of r is calculated by using the following formula: r = t × v1 ÷ 2, t being a disturbance duration, v1 being a flight speed of the unmanned aerial vehicle, and the value of t being the test result of the single scale model test; and
(2) a ferromagnetic target detection radius calculation step:
calculating the ferromagnetic target detection radius R according to the following formula:
$$\frac{R}{r} = p \frac{{e}^{- {k}_{1} {L}_{1}} \left(1 + V + {\text{V}}_{\partial } ⋅ \text{D}\right) M ⋅ s i n {θ}_{1} \frac{1}{{k}_{2} {l}_{1} {}^{{n}_{1}}}}{{e}^{- {k}_{2} {L}_{2}} \left(1 + v + {v}_{\partial } ⋅ \text{d}\right) m ⋅ s i n {θ}_{2} \frac{1}{{k}_{2} {l}_{2} {}^{{n}_{1}}}}$$
where e is a base number of a natural logarithm, k₁ is an attenuation coefficient of sea water to a magnetic field, and k₂ is an attenuation coefficient of air to the magnetic field.

2. The inverse estimation-based radius calculation method for ferromagnetic target detection according to claim 1, wherein a derivation process of the formula in the ferromagnetic target detection radius calculation step comprises:
(1) acquiring the following empirical formulas according to test results of multiple scale model tests:
$$\frac{{H}_{{θ}_{2}}}{{H}_{{θ}_{1}}} = \frac{1}{{k}_{2} {l}_{1} {}^{{n}_{1}}} ;$$
$$\frac{{H}_{{θ}_{2}}}{{H}_{{θ}_{1}}} = {e}^{- {k}_{1} {L}_{1}}$$
wherein H_{θ2} and H_{θ1} are respectively power frequency electromagnetic wave intensities at two different points in the same medium layer, l₁ is a distance between two points in the air layer, L₁ is a distance between two points in the sea water layer, the medium layer is the air layer or the sea water layer, and the multiple scale model tests comprise a scale model stationary test and a scale model motion test;
(2) performing inverse estimation separately for the air layer and the sea water layer according to the test results and the empirical formulas and in consideration of both a stationary state and a motion state of the scale model, so as to acquire an empirical formula for calculating a power frequency electromagnetic wave intensity B₂:
$${B}_{2} = - \frac{π S I}{{λ}^{2} {r}_{\text{0}}} {\text{e}}^{- {k}_{1} {L}_{2}} \left(1 + v + {v}_{\partial } ⋅ d\right) m ⋅ s i n {θ}_{2} \frac{1}{{k}_{2} {l}_{2} {}^{{n}_{1}}}$$
where π is Pi, S is a total area of a dipole group, I is current intensity, λ is a wavelength of power frequency electromagnetic waves, m is the mass of the scale model, v is a movement speed of a detection target, v_{∂} is an estimated change speed of the target, d is a diameter of the target, θ₂ is a detection included angle, L₂ is a depth of the detection target in sea water, and l₂ is a height of a detection point; and
(3) performing inverse estimation according to the empirical formula for H_{θ} to acquire a ferromagnetic target detection radius calculation formula:
$$\frac{R}{r} = \frac{- \frac{π S I}{{λ}^{2} {r}_{\text{0}}} {e}^{- {k}_{1} {L}_{1}} \left(1 + V + {\text{V}}_{\partial } ⋅ \text{D}\right) M ⋅ s i n {θ}_{1} \frac{1}{{k}_{2} {l}_{1} {}^{{n}_{1}}}}{- \frac{π S I}{{λ}^{2} {r}_{0}} {e}^{- {k}_{1} {L}_{2}} \left(1 + v + {v}_{\partial } ⋅ \text{d}\right) m ⋅ s i n {θ}_{2} \frac{1}{{k}_{2} {l}_{2} {}^{{n}_{1}}}}$$
wherein said formula is used to acquire the formula in the ferromagnetic target detection radius calculation step.

3. The inverse estimation-based radius calculation method for ferromagnetic target detection according to claim 2, wherein H₂ and h₂ both have multiple different values in each of the multiple scale model tests.

4. The inverse estimation-based radius calculation method for ferromagnetic target detection according to claim 1, wherein in the data acquisition step, n₁ is a preset natural number, the value of k₁ is 0.357, and the value of k₂ is 61.24.

5. An inverse estimation-based radius calculation system for ferromagnetic target detection, the system being used to inversely estimate, according to a test result of a single scale model stationary test or scale model motion test, a ferromagnetic target detection radius R in a corresponding ferromagnetic target stationary test or ferromagnetic target motion test, and the system comprising the following modules:
a data acquisition module, configured to perform the following:
respectively acquiring values of a model detection radius r, a ratio p of the mass of a ferromagnetic target to the mass of a scale model, a diving depth L₁ of the ferromagnetic target, a depth L₂ of the scale model in sea water, an attenuation index n₂ of power frequency electromagnetic wave intensity in a sea water layer with respect to a distance, a height l₁ of a ferromagnetic target detection platform, a flight height l₂ of an unmanned aerial vehicle, a speed V of the ferromagnetic target, a speed v of the scale model, an orientation change speed V_{∂} of the ferromagnetic target, an orientation change speed V_{∂} of the scale model, a ferromagnetic target included angle θ₁, a scale model included angle θ₂, a diameter D of the ferromagnetic target, and a diameter d of the scale model,
wherein the value of r is calculated by using the following formula: r = t × v1 ÷ 2, t being a disturbance duration, v1 being a flight speed of the unmanned aerial vehicle, and the value of t being the test result of the single scale model test; and
a ferromagnetic target detection radius calculation module, configured to perform the following:
calculating the ferromagnetic target detection radius R according to the following formula:
$$\frac{R}{r} = \frac{- \frac{π S I}{{λ}^{2} {r}_{\text{0}}} {e}^{- {k}_{1} {L}_{1}} \left(1 + V + {\text{V}}_{\partial } ⋅ \text{D}\right) M ⋅ s i n {θ}_{1} \frac{1}{{k}_{2} {l}_{1} {}^{{n}_{1}}}}{- \frac{π S I}{{λ}^{2} {r}_{0}} {e}^{- {k}_{1} {L}_{2}} \left(1 + v + {v}_{\partial } ⋅ \text{d}\right) m ⋅ s i n {θ}_{2} \frac{1}{{k}_{2} {l}_{2} {}^{{n}_{1}}}}$$
where e is a base number of a natural logarithm, k₁ is an attenuation coefficient of sea water to a magnetic field, and k₂ is an attenuation coefficient of air to the magnetic field.

6. The inverse estimation-based radius calculation system for ferromagnetic target detection according to claim 5, wherein a derivation operation of the formula in the ferromagnetic target detection radius calculation module comprises:
(1) acquiring the following empirical formulas according to test results of multiple scale model tests:
$$\frac{{H}_{{θ}_{2}}}{{H}_{{θ}_{1}}} = \frac{1}{{k}_{2} {l}_{1} {}^{{n}_{1}}} ;$$
$$\frac{{H}_{{θ}_{2}}}{{H}_{{θ}_{1}}} = {e}^{- {k}_{1} {L}_{1}}$$
wherein H_{θ2} and H_{θ1} are respectively power frequency electromagnetic wave intensities at two different points in the same medium layer, l₁ is a distance between two points in the air layer, L₁ is a distance between two points in the sea water layer, the medium layer is the air layer or the sea water layer, and the multiple scale model tests comprise a scale model stationary test and a scale model motion test;
(2) performing inverse estimation separately for the air layer and the sea water layer according to the test results and the empirical formulas and in consideration of both a stationary state and a motion state of the scale model, so as to acquire an empirical formula for calculating a power frequency electromagnetic wave intensity H_{θ}:
$${B}_{2} = - \frac{π S I}{{λ}^{2} {r}_{\text{0}}} {\text{e}}^{- {k}_{1} {L}_{2}} \left(1 + v + {v}_{\partial } ⋅ d\right) m ⋅ s i n {θ}_{2} \frac{1}{{k}_{2} {l}_{2} {}^{{n}_{1}}}$$
where π is Pi, S is a total area of a dipole group, I is current intensity, λ is a wavelength of power frequency electromagnetic waves, m is the mass of the scale model, v₀ is a movement speed of a detection target, v_{∂} is an orientation change speed of the scale model, d is a diameter of the scale model, θ is a detection included angle, L₂ is a depth of the detection target in sea water, and l₂ is a height of a detection point; and
(3) performing inverse estimation according to the empirical formula for H_{θ} to acquire a ferromagnetic target detection radius calculation formula:
$$\frac{R}{r} = \frac{- \frac{π S I}{{λ}^{2} {r}_{\text{0}}} {e}^{- {k}_{1} {L}_{1}} \left(1 + V + {\text{V}}_{\partial } ⋅ \text{D}\right) M ⋅ s i n {θ}_{1} \frac{1}{{k}_{2} {l}_{1} {}^{{n}_{1}}}}{- \frac{π S I}{{λ}^{2} {r}_{0}} {e}^{- {k}_{1} {L}_{2}} \left(1 + v + {v}_{\partial } ⋅ \text{d}\right) m ⋅ s i n {θ}_{2} \frac{1}{{k}_{2} {l}_{2} {}^{{n}_{1}}}}$$
wherein said formula is used to acquire the formula in the ferromagnetic target detection radius calculation module.

7. The inverse estimation-based radius calculation system for ferromagnetic target detection according to claim 6, wherein L₂ and l₂ both have multiple different values in each of the multiple scale model tests.

8. The inverse estimation-based radius calculation system for ferromagnetic target detection according to claim 5, wherein in the data acquisition module, n₁ and n₂ are both preset natural numbers, the value of k₁ is 0.357, and the value of k₂ is 61.24.

9. An inverse estimation-based radius calculation device for ferromagnetic target detection, comprising a memory and a processor, wherein the memory is used to store a computer program, and the processor, when executing the computer program, implements the inverse estimation-based radius calculation method for ferromagnetic target detection according claim 1.

10. A computer-readable storage medium, characterized in that the storage medium stores a computer program, and when executed by a processor, the computer program implements the inverse estimation-based radius calculation method for ferromagnetic target detection according to claim 1.
